(19) United States
(12) Patent Application Publication
(10) Pub. No.: US 2016/0218852 A1
(43) Pub. Date: Jul. 28, 2016

(54) HALF-DUPLEX SAWLESS RECEIVER

(71) Applicant: QUALCOMM Incorporated, San Diego, CA (US)

(72) Inventor: Prashanth Akula, San Diego, CA (US)

(21) Appl. No.: 14/602,576

(22) Filed: Jan. 22, 2015

(51) Int. Cl. H04L 5/16; H04B 1/00; H03F 3/217; H04W 72/04; H03F 3/19; H03F 3/21

(52) U.S. Cl. CPC H04L 5/16; H03F 3/19; H03F 3/211; H03F 3/217; H04W 72/0453; H04B 1/0082; H03F 2200/451; H03F 2203/21109

(57) ABSTRACT

An apparatus including: a first amplifier configured to amplify an input signal from multiple bands within a first frequency band class; and a plurality of downconverters coupled to the first amplifier, each downconverter configured to downconvert in one band of the multiple bands.

### BACKGROUND

1. Field

This invention relates generally to receivers for a wireless device, and more specifically, to sawless receivers operating in a half-duplex mode.

2. Background

In a full duplex, frequency division duplex (FD-FDD) system, the receiver and transmitter operate simultaneously on different frequencies, which provide the necessary separation between uplink and downlink signal paths. However, current radio frequency (RF) front-end (FE) design for an FDD long-term evolution (LTE) and carrier aggregation (CA) transceiver is very complex. For example, each band of the FDD transceiver may need a surface acoustic wave (SAW) filter, a duplexer, and a low noise amplifier (LNA). For inter-band CA, where the wanted signal channels are in different reception bands, the FE design is even more complex because it may require a separate antenna for the second CA path and a new LNA port. Further, a separate SAW filter is needed for each reception band, where each filter is usually followed by a dedicated LNA or LNA input stage tuned to that reception band. The bandwidth of the LNA following the SAW filter may be insufficient for simultaneous reception of channels at different reception bands. A separate local oscillator (LO) signal having a different frequency is therefore needed for each reception band for signal down conversion. Each separate LO signal (I and Q) requires a separate analog and digital baseband signal processing circuit. Inter-band CA therefore requires parallel radio receivers, for example, one receiver chain for each simultaneously utilized reception band.

Because LNAs typically use on-chip inductors, which require large silicon area, using two or more parallel LNAs requires a significant amount of silicon area. The LNA input also has to be matched in all modes of operation, including when there is only one active LNA or when there are two or more parallel LNAs. Further, the requirements for sufficient input matching and the noise figure (NF) regardless of the number of parallel LNAs means that the number of parallel devices connected to the RF input increases relative to the case where only one LNA is used in all modes of receiver operation. The higher number of parallel input devices means higher parasitic capacitances at the receiver RF input, which causes problems with input matching. Using multiple parallel LNAs also significantly increases the supply current of the RF front-end. Thus, the use of parallel LNAs in parallel receivers is not desirable, especially if LNAs use on-chip inductors.

### BRIEF DESCRIPTION OF THE DRAWINGS

The details of the present disclosure, both as to its structure and operation, may be gleaned in part by study of the appended further drawings, in which like reference numerals refer to like parts, and in which:

FIG. 1 is a representation of an exemplary wireless device communicating with a wireless communication system;

FIG. 2 is a block diagram of an exemplary RF front-end design of a transceiver that can be used in a wireless device in accordance with one embodiment of the present disclosure;

FIG. 3 is a detailed block diagram of the receiver in accordance with one embodiment of the present disclosure;

FIG. 4A is a block diagram of the receiver showing the selection of a band class for an LNA and bands for the demodulators within the selected band class; and

FIG. 4B is a block diagram of the receiver showing the selection of two band classes for a pair of LNAs and bands for the demodulators within the selected band classes.

### DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

Various embodiments as described below provide for operating the front-end of a transceiver in a half-duplex (HD) operation, while using the same carrier frequency in a time division duplex (TDD) mode where the time domain provides the uplink and downlink separation. Further, using the transceiver in an HD operation enables a SAW-less configuration for the receiver that is operating in the TDD mode with carrier aggregation (CA). Thus, the SAW-less LTE receiver for HD/TDD CA mode can be implemented using a simpler, more cost-efficient approach whose complexity does not scale with the number of HD frequency bands supported.

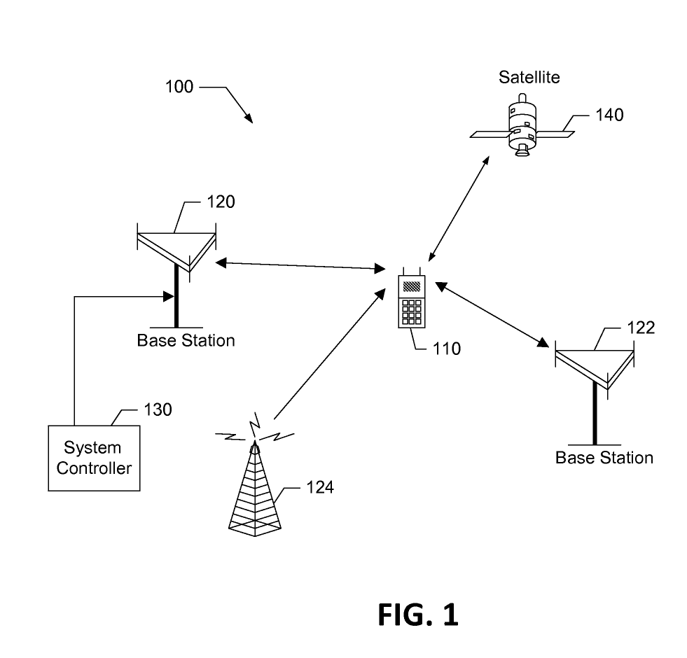

FIG. 1 is a representation of an exemplary wireless device 110 communicating with a wireless communication system 100. Wireless system 100 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows wireless system 100 including two base stations 120 and 122 and one system controller 130. In general, a wireless system may include any number of base stations and any set of network entities.

Wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 110 may communicate with wireless system 100. Wireless device 110 may also receive signals from broadcast stations (e.g., a broadcast station 124), signals from satellites (e.g., a satellite 140) in one or more global navigation satellite systems (GNSS), etc. Wireless device 110 may support one or more radio technologies for wireless communication such as LTE, WCDMA, CDMA 1×, EVDO, TD-SCDMA, GSM, 802.11, etc.

Wireless device 110 may support CA, which is operation on multiple carriers with multiple downlinks (DL) and multiple uplinks (UL) for LTE-advanced technology in FDD and TDD modes. Thus, CA may also be referred to as multi-carrier operation. A carrier may refer to a range of frequencies used for communication and may be associated with certain characteristics. For example, a carrier may be associated with system information and/or control information describing operation on the carrier. A carrier may also be referred to as a component carrier (CC), a frequency channel, a cell, etc. A band may include one or more carriers. Each carrier may cover up to 20 MHz in LTE. Wireless device 110 may be configured with up to 5 carriers in one band. Each band class may include multiple frequency bands. For example, a low-band class may include bands B5, B12, B13, a mid-band class may include bands B1, B2, B3, and a high-band class may include bands B7, B22, B40, and B41.

As stated above, the current radio frequency (RF) front-end (FE) design for an FDD long-term evolution (LTE) and carrier aggregation (CA) transceiver is very complex. For example, each band of the FDD transceiver may need a SAW filter, a duplexer, and a low noise amplifier (LNA). For inter-band CA, the FE design is even more complex because it may require a separate antenna for the second CA path and a new LNA port. Further, a separate SAW filter is needed for each reception band, where each filter is usually followed by a dedicated LNA or LNA input stage tuned to that reception band. The bandwidth of the LNA following the SAW filter may be insufficient for simultaneous reception of channels at different reception bands. A separate local oscillator (LO) signal having a different frequency is therefore needed for each reception band for signal down conversion. Each separate LO signal (I and Q) requires a separate analog and digital baseband signal processing circuit. Inter-band CA therefore requires parallel radio receivers, for example, one receiver chain for each simultaneously utilized reception band. Accordingly, the current RF FE design is complex for an FDD LTE and CA transceiver.

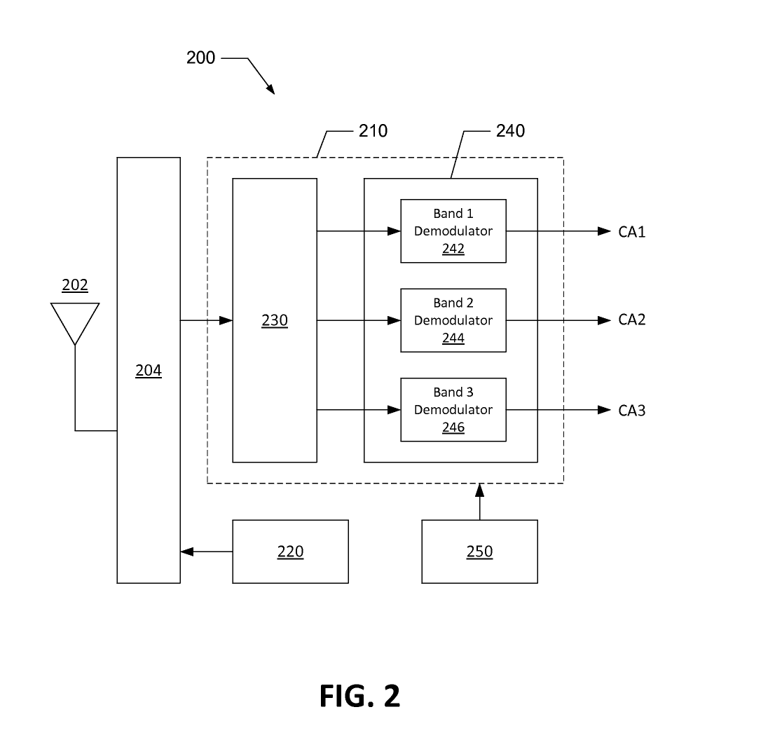

FIG. 2 is a block diagram of an exemplary RF front-end design 200 of a transceiver that can be used in a wireless device (e.g., wireless device 110 in FIG. 1) in accordance with one embodiment of the present disclosure. In the illustrated embodiment of FIG. 2, the front-end design 200 includes an antenna 202, an antenna interface system 204, a transmitter 220, and a receiver 210. The antenna interface system 204 isolates the receiver 210 from the transmitter 220 while permitting them to share the antenna 202. During operation, RF signals received by the antenna 202 are passed to the antenna interface system 204, which includes, in one embodiment, matching circuits configured to provide impedance matching to enable the RF signals from the antenna 202 to be input to the receiver 210 with low loss or distortion. Although the illustrated embodiment of FIG. 2 shows only one antenna 202, multiple antennas can be used to receive and transmit various signals including receiving and transmitting various carriers in a communication system that utilizes carrier aggregation. Further, the RF front-end design 200 of FIG. 2 is configured in a SAW-less configuration for the receiver that is operating in the HD/TDD mode with CA. In FIG. 2, the SAW-less configuration is characterized by the absence of any RF/SAW filter between the antenna 202 and the receiver 210.

In the SAW-less configuration of FIG. 2, the receiver 210 includes an LNA system 230 and a demodulator system 240. The LNA system 230 is configured to efficiently use the LNAs that would minimize the number of elements in the system 230. The LAN system 230 operates to amplify the RF signals received by the antenna 202 and direct the amplified signals to a particular demodulator in a multiband receiver under the control of a controller 250. The LNA system 230 is configured to direct the amplified signals to the demodulator system 240 which includes three demodulators 242, 244, 246 for demodulating signals in three different frequency bands for a particular band class (e.g., low, mid, or high). Although the demodulator system 240 in FIG. 2 shows only three demodulators 242, 244, 246, more than three demodulators operating in more than three different bands can be configured. Further, in FIG. 2, since all LTE bands of the RF signals are divided into only three frequency band classes, LNAs in the LNA system 230 needs to be broadband and highly linear.

The transceiver RF front-end design 200 may be configured to operate in low-band (LB) covering frequencies lower than 1000 megahertz (MHz), mid-band (MB) covering frequencies from 1000 MHz to 2300 MHz, and/or high-band (HB) covering frequencies higher than 2300 MHz. For example, low-band may cover 698 to 960 MHz, mid-band may cover 1475 to 2170 MHz, and high-band may cover 2300 to 2690 MHz. An ultra-high band may cover 3400 to 3800 MHz. Low-band, mid-band, and high-band refer to three classes of bands (or band classes), with each band class including a number of frequency bands (or simply, “bands”). Each band may cover up to 200 MHz. LTE Release 11 supports 35 bands, which are referred to as LTE/UMTS bands and are listed in a publicly available document 3GPP TS 36.101. In general, any number of band classes may be defined. Each band class may cover any range of frequencies, which may or may not match any of the frequency ranges given above. Each band class may include any number of bands.

The demodulator system 240 operates to downconvert the RF signals to the baseband. Thus, terms “demodulator” and “demodulator system” can be interchangeably used with terms “downconverter” and “downconverter system”. The baseband signals may then be combined or otherwise processed at the receiving device. For example, in a CA communication system, each carrier is received and demodulated at a receiver to obtain its corresponding baseband signal component. These baseband signal components are then combined to form the original baseband signal. Although it is not shown in FIG. 2, a de-multiplexer can be used to combine the components to form the original baseband signal. The controller 250 controls how the LNA system 230 amplifies and directs signals to the demodulator system 240. For example, the controller 250 controls which LNA(s) and band modulator(s) are selected.

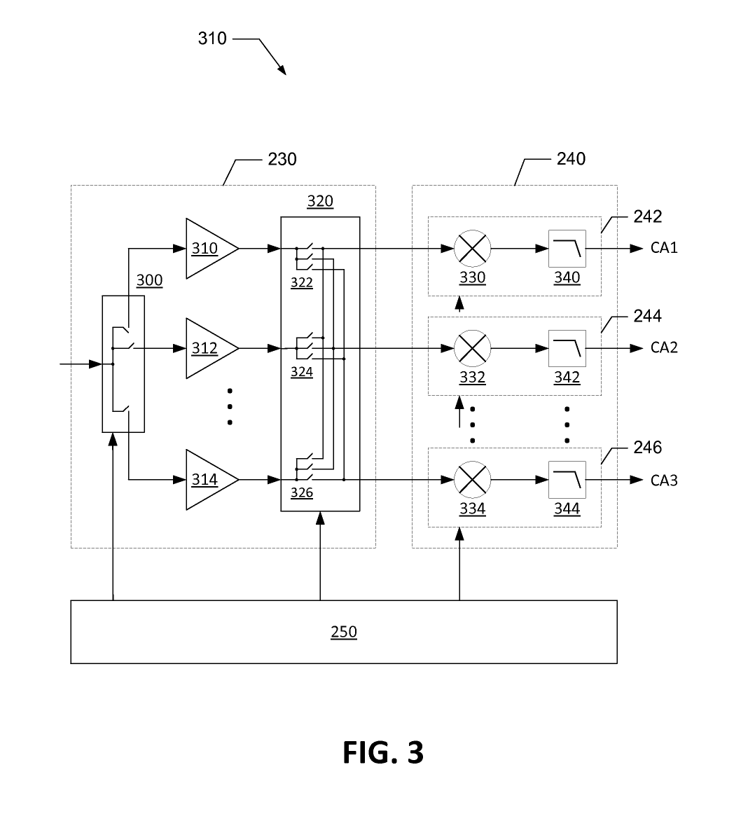

FIG. 3 is a detailed block diagram of the receiver 210 in accordance with one embodiment of the present disclosure. As described before, the receiver 210 includes the LNA system 230 and the demodulator system 240. In the illustrated embodiment of FIG. 3, the LNA system includes a multiplexer, depicted in this embodiment as a triplexer 300. The LNA system further includes three LNAs 310, 312, 314 and a reconfigurable 3×3 switch apparatus 320 comprising multiple switches 322, 324, 326 that are independently controllable by the controller 250. The controller 250 selects an LNA 310, 312, or 314 tuned to a particular frequency band class (e.g., low, mid, or high) using the triplexer 300. In one embodiment, the controller 250 uses the reconfigurable switch apparatus 320 to allow each LNA 310, 312, 314 to utilize one, two, or all three demodulators 242, 244, 246. In another embodiment, the controller 250 uses the reconfigurable switch apparatus 320 to use one, two, or all three LNAs 310, 312, 314 and demodulators 242, 244, 246 to enable inter-band CA. Although a triplexer is used in this embodiment to couple one, two, or three LNAs to one, two, or three demodulator 242, 244, 246, a multiplexer can be used to couple any number of LNAs to any number of demodulators.

The controller 250 also controls/selects a plurality of demodulators 242, 244, 246 tuned to demodulate the aggregated carriers down to the baseband. Each demodulator 242, 244, 246 in the demodulator system 240 includes a mixer 330, 332, 334 and a baseband filter 340, 342, 344. The controller 250 controls the local oscillator frequency input to the mixers to select a particular band within the particular frequency band class selected with the triplexer 300 and an LAN 310, 312, or 314. For example, assuming LNA 310 is configured for a low frequency band class, the controller 250 selects LNA 310 using the triplexer 300 to select the low frequency band class. That is, LNA 310 is tuned for a frequency band covering 698 to 960 MHz. The controller 250 also selects switches 322 in the reconfigurable switch apparatus 320 so that the output of the LNA 310 is directed to each of the demodulators 242, 244, 246. The controller 250 further controls the local oscillators fed to the mixers 330, 332, 334 to control the frequency bands of each of the demodulators 242, 244, 246. For example, the output of the demodulator 242 outputs a CA1 signal at band 5, the output of the demodulator 244 outputs a CA2 signal at band 12, and the output of the demodulator 246 outputs a CA3 signal at band 13. Bands 5, 12, and 13 are all within the low frequency band class.

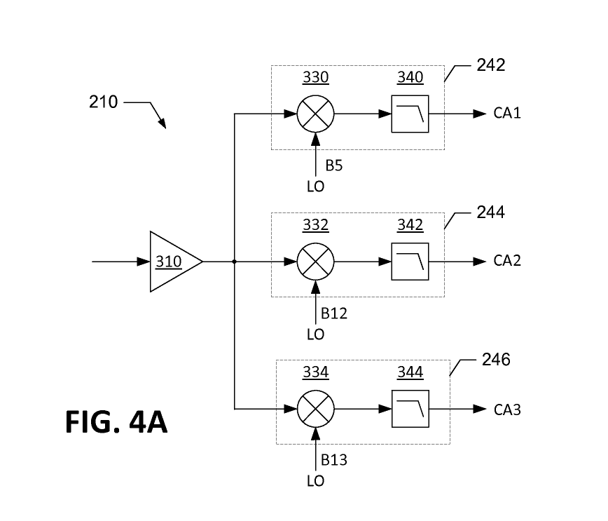

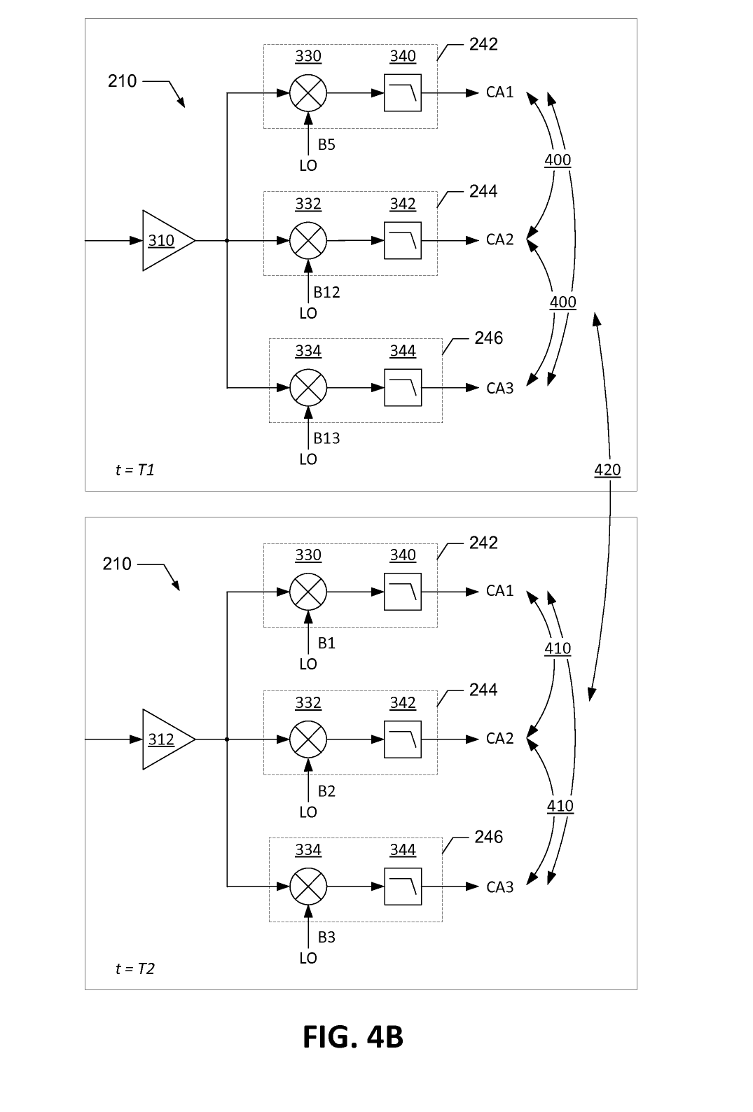

FIG. 4A is a block diagram of the receiver 210 showing the selection of a band class for an LNA and bands for the demodulators within the selected band class. In the illustrated embodiment of FIG. 4A, LNA 310 is configured for a low frequency band class covering 698 to 960 MHz. Further, the output of the LNA 310 is coupled to the demodulators 242, 244, 246. The demodulator 242 includes a mixer 330 and a baseband filter 340. The mixer 330 is configured to downconvert the RF signal output from the LNA 310 to low band B5 (CA1) using the adjusted local oscillator. The demodulator 244 includes a mixer 332 and a baseband filter 342. The mixer 332 is configured to downconvert the RF signal output from the LNA 310 to low band B12 (CA2) using the adjusted local oscillator. The demodulator 246 includes a mixer 334 and a baseband filter 344. The mixer 334 is configured to downconvert the RF signal output from the LNA 310 to low band B13 (CA3) using the adjusted local oscillator. Thus, signals CA1, CA2, and CA3 are intra-band CA signals.

FIG. 4B is a block diagram of the receiver 210 showing the selection of two different band classes at two different times showing the inter-band carrier aggregation (CA). In the illustrated embodiment of FIG. 4B, the selected LNA 310 is configured for a low frequency band class (at time T1) and the selected LNA 312 is configured to a mid-frequency band class (at time T2). Further, the output of the LNA 310 is coupled to the demodulators 242, 244, 246 at time T1, while the output of the LNA 312 is coupled to the demodulators 242, 244, 246 at time T2.

The demodulator 242 includes a mixer 330 and a baseband filter 340. The demodulator 244 includes a mixer 332 and a baseband filter 342. The demodulator 246 includes a mixer 334 and a baseband filter 344. At time T1, the mixer 330 is configured to downconvert the RF signal output from the LNA 310 to low band B5 (CA1) using the adjusted local oscillator; the mixer 332 is configured to downconvert the RF signal output from the LNA 310 to low band B12 (CA2) using the adjusted local oscillator; and the mixer 334 is configured to downconvert the RF signal output from the LNA 310 to low band B13 (CA3) using the adjusted local oscillator. Thus, signals CA1, CA2, and CA3, at time T1, are intra-band CA signals 400. At time T2, the mixer 330 is configured to downconvert the RF signal output from the LNA 312 to mid-band B1 (CA1) using the adjusted local oscillator; the mixer 332 is configured to downconvert the RF signal output from the LNA 312 to mid-band B2 (CA2) using the adjusted local oscillator; and the mixer 334 is configured to downconvert the RF signal output from the LNA 312 to mid-band B3 (CA3) using the adjusted local oscillator. Thus, signals CA1, CA2, and CA3, at time T2, are intra-band CA signals 410, while signals CA1, CA2, and CA3 signals between times T1 and T2 are inter-band signals 420.

Receiver chips and LNAs described herein may be implemented on an IC, an analog IC, an RFIC, a mixed-signal IC, an ASIC, a printed circuit board (PCB), an electronic device, etc. The receiver chips and LNAs may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), hetero junction bipolar transistors (HBTs), high electron mobility transistors (HEMTs), silicon-on-insulator (SOI), etc.

An apparatus implementing the receiver chips and LNAs described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein but is to be accorded the widest scope consistent with the principles and novel features disclosed herein.

What is claimed is:

1. An apparatus comprising:
a first amplifier configured to amplify an input signal from multiple bands within a first frequency band class; and
a plurality of downconverters coupled to the first amplifier, each downconverter configured to downconvert in one band of the multiple bands.

2. The apparatus of claim 1, the plurality of downconverters comprising a plurality of mixers.

3. The apparatus of claim 1, further comprising
at least one additional amplifier configured to amplify the input signal from multiple bands within at least one additional frequency band class.

4. The apparatus of claim 3, further comprising
a multiplexer coupled to the first amplifier and the least one additional amplifier, the multiplexer configured to direct the input signal to one of the first amplifier and the at least one additional amplifier based on the multiple bands within the first frequency band class and the at least one additional frequency band class.

5. The apparatus of claim 3, further comprising
a switch apparatus configured to couple outputs of the first amplifier and the at least additional amplifier to the plurality of downconverters.

6. The apparatus of claim 5, the switch apparatus is operable in response to a plurality of control signals.

7. The apparatus of claim 6, the switch apparatus comprising
a plurality of switches coupled to the plurality of control signals.

8. The apparatus of claim 7, each of the plurality of switches comprises a plurality of independently controllable switch devices that are independently controlled by the plurality of control signals.

9. The apparatus of claim 7, the plurality of switches couples the plurality of downconverters to each of the at least one additional amplifiers.

10. The apparatus of claim 1, each of the plurality of downconverters coupled to the first amplifier is configured to downconvert in one band of the multiple bands in the first frequency band class.

11. The apparatus of claim 1, each downconverter of the plurality of converters is configured to receive a local oscillator signal.

12. The apparatus of claim 11, each downconverter is configured to mix the input signal with the local oscillator signal to downconvert the input signal into a baseband signal.

13. The apparatus of claim 12, further comprising a baseband filter configured to filter the baseband signal.

14. An apparatus comprising:
first means for amplifying an input signal from multiple bands within a first frequency band class; and
plural means for downconverting coupled to the first means for amplifying, each means for downconverting configured to downconvert in one band of the multiple bands.

15. The apparatus of claim 14, further comprising
at least one additional means for amplifying configured to amplify the input signal from multiple bands within at least one additional frequency band class.

16. The apparatus of claim 15, further comprising
means for directing the input signal coupled to the first means for amplifying and the at least one additional means for amplifying, the means for directing configured to direct the input signal to one of the first means for amplifying and the at least one additional means for amplifying based on the multiple bands within the first frequency band class and the at least one additional frequency band class.

17. The apparatus of claim 14, each of the plural means for downconverting comprises means for receiving a local oscillator signal.

18. The apparatus of claim 17, the means for receiving a local oscillator signal comprises means for mixing the input signal with the local oscillator signal to downconvert the input signal into a baseband signal.

19. A method comprising:
amplifying an input signal from multiple bands within a first frequency band class using a first amplifier;
coupling a plurality of downconverters to the first amplifier; and
downconverting in one band of the multiple bands using each of the plurality of downconverters.

20. The method of claim 19, further comprising
directing the input signal to one of the first amplifier and at least one additional amplifier based on the multiple bands within the first frequency band class and at least one additional frequency band class.
